(19) United States
(12) Patent Application Publication
(10) Pub. No.: US 2025/0202194 A1
(43) Pub. Date: Jun. 19, 2025

(54) LASER PACKAGE AND METHOD FOR DETERMINING A LASER LIGHT OFFSET IN A LASER PACKAGE

(71) Applicant: ams-OSRAM International GmbH, Regensburg (DE)

(72) Inventors: Nicole BERNER, Walderbach (DE); Jan MARFELD, Regensburg (DE); Jan SEIDENFADEN, Neumarkt i.d Oberpfalz (DE); Erik HEINEMANN, Regensburg (DE)

(73) Assignee: ams-OSRAM International GmbH, Regensburg (DE)

(21) Appl. No.: 18/833,043

(22) PCT Filed: Jan. 27, 2023
(86) PCT No.: PCT/EP2023/052078

§ 371 Date: Jul. 25, 2024

(30) Foreign Application Priority Data
Jan. 28, 2022 (DE) 10 2022 102 088.6

(51) Int. Cl. H01S 5/0683; H01S 5/02257; H01S 5/0239

(52) U.S. Cl. CPC H01S 5/0683; H01S 5/02257; H01S 5/0239

(57) ABSTRACT

The invention relates to a method for determining a laser light offset in a laser package having a carrier substrate, at least one laser device arranged on the carrier substrate for emitting laser light surrounded by a housing cover, the housing cover having a light exit window through which a laser beam is emitted from the laser package during the intended use of the laser package. The method comprises the following steps: providing the laser package with at least one photosensitive area on a surface of the housing cover and/or carrier substrate; energizing the at least one laser device so that it emits a laser beam; and deflecting the emitted laser beam in the direction of the at least one photosensitive area to generate a position marker on the at least one photosensitive area; wherein the position marker indicates the position and/or direction of the center axis of the laser beam relative to a target position and/or target direction, and wherein the position marker and/or target position and/or target direction is relative to at least one reference on the housing cover and/or the carrier substrate.

### CROSS-REFERENCE TO RELATED APPLICATIONS

The present application is a national stage entry from International Application No. PCT/EP2023/052078, filed on Jan. 27, 2023, published as International Publication No. WO 2023/144343 A1 on Aug. 3, 2023, and claims the priority of German patent application No. 10 2022 102 088.6 dated Jan. 28, 2022, the disclosures of which are hereby incorporated by reference into the present application.

### FIELD

The present invention relates to a laser package with a position marker for determining a laser light offset in the laser package and a method for determining a laser light offset in a laser package.

### BACKGROUND

When using lasers, laser components or laser packages in an application, very precise alignment of a beam coupled out of the laser package into another system connected to the laser package (e.g. optics) is usually necessary. This can be done either by active alignment (the laser package is actively operated when aligning the package or when aligning the other system) or by passive alignment (the package housing or predefined markings on the housing are aligned when the laser package is inactive, e.g. alignment of a metallization edge to the base plate or to fiducals on the housing cover of the package). Active alignment is very time-consuming, slow and cost-intensive. In addition, active alignment has so far been possible almost exclusively with a snap-curing or UV-curing process, in which the laser package is first fixed in place using an adhesive and then cured in position. This limits the interconnect options, the sequence of the process flow and the number of successive assembly steps. With passive alignment, on the other hand, only the housing or recognizable reference markers (fiducals) are used for alignment. Tolerances of the individual components and tolerances that can arise during the assembly process when manufacturing the laser package therefore add up, which is why it is often not possible to achieve sufficient precision using passive alignment. Passive alignment is therefore more cost-effective, but significantly less precise.

If high-precision alignment of the laser package is required in an application, the laser package itself or the other components of the application must be actively aligned at this time. This means that the laser package must be actively operated during alignment. However, this is very time-consuming, slow and cost-intensive, and the interconnect options, the sequence of the process flow and the number of consecutive assembly steps are limited.

There is therefore a need to provide an improved laser package that makes it easier to adjust the laser package in an application and counteracts at least one of the aforementioned problems.

### SUMMARY OF THE INVENTION

This need is met by a method mentioned in claim 1 for determining a laser light offset in a laser package. Claim 15 recites the features of a laser package according to the invention comprising a position marker for determining a laser light offset in the laser package. Further embodiments are the subject of the subclaims.

The core idea of the invention is to allow high-precision passive alignment of a laser package in an application. For this purpose, the laser package comprises a position marker on an outer surface of the housing of the laser package which indicates a possible laser light offset in the laser package. The laser light offset can be an offset of the laser beam actually emitted by the laser package in relation to the target position and target direction of a laser beam ideally emitted by the laser package. The laser light offset can occur, for example, due to component tolerances of the individual components of the laser package or tolerances during the manufacturing process of the laser package. The position marker is generated after the laser package has been assembled so that it is independent of possible tolerances and is related to a reference on the housing of the laser package so that the exact position and direction of the laser light emitted from the laser package can be determined on the basis of the reference and the position marker. The laser package can then be passively and yet highly precisely adjusted in an application using this information.

To generate the position marker, a photosensitive area is provided on the laser package housing, which is exposed by means of a laser beam emitted by the laser package after the laser package has been assembled during laser operation. By exposing the photosensitive area to light, the position marker is generated, in particular in the area where the laser beam strikes the photosensitive area. As the position marker can be generated directly after the laser package has been assembled, for example during final testing, the technical effort required to generate this marking is significantly reduced compared to active adjustment of the laser package.

At least one embodiment proposes a method for determining a laser light offset in a laser package, or a method for generating a position marker on the laser package. The laser package comprises a carrier substrate and at least one laser device arranged on the carrier substrate for emitting laser light. The at least one laser device is surrounded by a housing cover or the housing cover forms a cavity with the carrier substrate in which the at least one laser device is arranged, and the housing cover has a light exit window through which a laser beam is emitted from the laser package during intended use of the laser package. The method for determining a laser light offset in the laser package or for generating a position marker on the laser package comprises the following steps:
Providing the laser package with at least one photosensitive area on a surface of the housing cover and/or carrier substrate, in particular on a surface of the housing cover and/or carrier substrate located outside the cavity;
Energizing the at least one laser device so that it emits a laser beam; and
Deflecting the emitted laser beam in the direction of the at least one photosensitive area to generate a position marker on the at least one photosensitive area;
wherein the position marker indicates the position and/or direction of the center axis of the laser beam relative to a target position and/or target direction, in particular the target position and/or target direction of a target direction of a laser beam ideally emitted by the laser package, and
wherein the position marker and/or target position and/or target direction is in relation to at least one reference on the housing cover and/or the carrier substrate.

In particular, the position marker indicates the position and/or direction of the center axis of the laser beam actually emitted by the laser package relative to a target position and/or target direction or relative to a target exit location and/or a target axis of a laser beam ideally emitted by the laser package or from the laser package. The position marker, target position and/or target direction is in relation to at least one reference on the housing cover and/or the carrier substrate, whereby the reference can be formed, for example, by a reference surface, a reference edge, a reference line, several reference points or the like, which is/are located on the housing cover and/or the carrier substrate. The exact position of the position marker and thus the exact position and direction of the laser beam emitted from the laser package in relation to the reference can be indicated by the relationship between the position marker, target position and/or target direction and the at least one reference. Using this information, the laser package can then be adjusted in relation to the at least one reference-even without activating the laser package, i.e. passively.

The position and/or direction of the center axis of the laser beam actually emitted by the laser package can deviate in particular from the nominal position and/or nominal direction of a laser beam ideally emitted by the laser package. For example, the actually emitted laser beam may be tilted and/or displaced and/or rotated relative to an ideal laser beam emitted from the laser package. Such tilting and/or shifting and/or twisting can result, for example, from component tolerances of the individual components of the laser package or tolerances in the manufacturing process of the laser package. Component tolerances of the individual components of the laser package and tolerances in the manufacturing process of the laser package can accordingly lead to an offset between the laser beam actually emitted by the laser package and an ideal laser beam emitted by the laser package. Using the position marker, the laser package can then be adjusted in an application according to the offset of the laser beam actually emitted in such a way that the laser beam can be precisely coupled into an element connected to the laser package, such as an optical system.

The photosensitive area can, for example, comprise a photosensitive layer that can be permanently or reversibly changed (e.g. a discoloration or a mechanical opening). Alternatively, the housing cover and/or the carrier substrate, for example, can also comprise a photosensitive material at least in the photosensitive area, which can be changed by the concentrated influence of light or the incidence of laser light.

According to at least one embodiment, the step of deflecting the laser beam is performed by means of a reflector module arranged opposite the light exit window. The step of deflecting the laser beam can accordingly comprise arranging a reflector module opposite the light exit window. The reflector module may, for example, be a prism, a mirror or a comparable element or module, by means of which the laser beam emitted by the at least one laser device is deflected in the direction of the at least one photosensitive area after the laser beam has been decoupled from the laser package through the exit window.

The step of arranging the reflector module opposite the light exit window can, for example, take place after the laser package has been assembled; in particular, the step of arranging the reflector module can take place during final testing of the laser package. The at least one laser device or the laser package is then activated or switched on as part of the final testing and the laser beam emitted by the laser device or the laser package is deflected by the reflector module in the direction of the at least one photosensitive area. As a result, a marking can be created on a photosensitive layer/photosensitive material of the at least one photosensitive area.

According to at least one embodiment, the reflector module is arranged opposite the light exit window in relation to the at least one reference. Accordingly, the structure for determining a laser light offset in the laser package or for generating the position marker on the laser package is always identical with respect to the at least one reference for several laser packages, so that the laser light offset of a laser package can always be specified with respect to the at least one reference. In relation to the at least one reference, this allows precise conclusions to be drawn about the position/direction/angle of the laser beam coupled out of the laser package by means of the position marker, without having to take into account the tolerances of the process chain or the various components of the laser package.

According to at least one embodiment, the position marker is generated by irradiating or exposing the at least one photosensitive area with the laser beam. By irradiating or exposing the at least one photosensitive area, a discoloration or a mechanical opening of a photosensitive layer or a photosensitive material is produced in or on the photosensitive area. This discoloration or mechanical opening can, for example, form the position marker.

According to at least one embodiment, the at least one photosensitive area is formed by an array of several photosensitive sub-areas. By irradiating or exposing the at least one photosensitive area, for example, only a number of the multiple photosensitive sub-areas can be colored or mechanically opened and thus form the position marker. In particular, a number of the several photosensitive sub-areas can mean a real subset of the several sub-areas, i.e. a number smaller than the number of the several sub-areas. In some embodiments, however, it may also be desirable for substantially all of the multiple sub-areas to be at least partially colored or mechanically opened.

According to at least one embodiment, the method further comprises providing a reference marker, in particular a crosshair, in the area or on the at least one photosensitive area. An offset between the reference marker and the position marker can in particular indicate a position and/or direction offset of the center axis of the laser beam relative to the target position and/or target direction of an ideal laser light emitted from the laser package.

According to at least one embodiment, the reference marker is in relation to the at least one reference on the housing cover and/or the carrier substrate, so that conclusions about the precise adjustment of the laser page in an application can be drawn retrospectively on the laser package.

According to at least one embodiment, the method further comprises sorting the laser package into a class, in particular laser class, wherein the laser package is sorted into a class according to the position of the position marker relative to the reference marker. Such a classification can also be called “binning”, in which laser packages are sorted into different classes according to their quality, emission color and/or emission direction after or during their manufacture. In the present case, binning can be realized, for example, in such a way that a laser package is found to be “good” if a position marker generated by means of the said process lies within a predetermined reference marker, or is found to be “not good” if a position marker generated by means of the said process lies at least partially outside the reference marker. Binning can also be realized in such a way that laser packages can be sorted into classes based on their position and/or directional offset of the central axis of the emitted laser beam (squint angle). For example, the laser packages can be sorted into classes in relation to a target coordinate system in such a way that a first class is formed by laser packages in which the center axis of the emitted laser beam lies around the origin of the target coordinate system, a second class is formed by laser packages in which the center axis of the emitted laser beam lies in the first square of the nominal coordinate system, a third class is formed by laser packages in which the center axis of the emitted laser beam lies in the second square of the nominal coordinate system, and so on. The origin of the nominal coordinate system can correspond to the center axis of an ideally emitted laser beam. An offset of the center axis of an actual emitted laser beam from the origin may correspondingly indicate a position and/or direction offset of the center axis of the emitted laser beam, and the laser packages may be classified according to a “similar” or substantially no position and/or direction offset.

According to at least one embodiment, the at least one photosensitive area is arranged on the exit window. The position marker is then generated by radiating through the at least one photosensitive area on the exit window. For example, this may be a layer or a thin film comprising a photosensitive material on the exit window. The exit window can be made of glass, for example. In this case, the laser beam is deflected by means of an optical element within the laser package, whereby the optical element is part of the laser package. In this case, the position marker can be created by irradiating or exposing the at least one photosensitive area by mechanically opening the photosensitive material in the area where the laser beam strikes the material. This mechanical opening can then form the position marker and indicate the position and/or direction of the laser beam emitted from the laser package. The photosensitive material can be “opened” by the laser beam itself, but it is also conceivable to remove the exposed material in a further step (similar to a paint that has been exposed).

There is further disclosed a laser package having a position marker for determining a laser light offset in the laser package. The laser package comprises a carrier substrate, at least one laser device arranged on the carrier substrate and configured to emit a laser beam, and a housing cover arranged on the carrier substrate and forming a cavity with the carrier substrate. The at least one laser device is arranged in the cavity, and the housing cover has a light exit window through which a laser beam is emitted from the laser package during intended use of the laser package. In addition, the laser package has at least one photosensitive area on a surface of the housing cover and/or carrier substrate located outside the cavity, as well as the position marker. The position marker is arranged on the at least one photosensitive area and indicates the position and/or direction of the center axis of the laser beam emitted during the intended use of the laser package relative to a target position and/or target direction. In addition, the position marker and/or target position and/or target direction is in relation to at least one reference on the housing cover and/or the carrier substrate.

In particular, the laser package can be a laser package manufactured, processed or measured using the above process.

According to at least one embodiment, the at least one photosensitive area is formed by an array of several photosensitive sub-areas. The photosensitive sub-areas can each comprise a photosensitive layer or a photosensitive material and can be arranged at a distance from one another in a matrix arrangement. There may be areas between the sub-areas that do not comprise photosensitive material.

According to at least one embodiment, the laser package further comprises a reference marker, in particular a crosshair, in the area or on the at least one photosensitive area. An offset between the reference marker and the position marker can in particular indicate a position and/or direction offset of the center axis of the laser beam relative to the target position and/or target direction of an ideal laser light emitted from the laser package. The reference marker may, for example, be a marking painted or printed on the at least one photosensitive area, such as a crosshair, a coordinate system or another type of target marking. However, it is also possible that the at least one photosensitive area already forms a reference marker due to its structure. For example, the photosensitive area can be formed by an array of several photosensitive sub-areas, whereby the array structure already provides a type of coordinate system and thus a target marking. It is also conceivable that the at least one photosensitive area has elevations or recesses that represent a target marker or reference marker.

According to at least one embodiment, the reference marker is in relation to the at least one reference on the housing cover and/or the carrier substrate, so that the laser package with the reference marker and the position marker can be used to draw conclusions about a position and/or direction offset of the center axis of the laser beam emitted by the laser package, thereby enabling precise adjustment of the laser package in an application.

According to at least one embodiment, the at least one photosensitive area is arranged on the exit window. Accordingly, the position marker can also be arranged on the exit window or on the at least one photosensitive area on the exit window. The position marker can be formed by a mechanically opened part of the at least one photosensitive area and can, for example, form a kind of aperture for the laser beam on the exit window.

According to at least one embodiment, the at least one laser device is formed by an edge-emitting laser diode. The laser device can be operated in pulsed mode during its intended use, for example. In some embodiments, however, it may also be desirable for it to be operated continuously.

According to at least one embodiment, the laser device is configured to emit blue, red, green, infrared or ultraviolet light. However, this should not be understood as limiting, as the laser device can also be configured to emit laser light of any other color.

According to at least one embodiment, the laser package comprises a first, a second and a third laser device or laser diode. The first laser device is configured to emit red laser light, the second laser device is configured to emit green laser light and the third laser device is configured to emit blue laser light. In particular, the laser package with the three laser devices or laser diodes can form a so-called RGB laser package. An RGB laser package can, for example, emit light of the colors red, green and blue as well as any mixed colors. In some embodiments, the laser package can also comprise more than three laser devices and form an RGB-IR laser package, for example. An RGB-IR laser package can, for example, emit light of the colors red, green, blue and infrared, as well as any mixed colors, such as white.

According to at least one embodiment, the at least one laser device is formed by a multi-ridge laser diode, in particular an edge-emitting multi-ridge laser diode, which has a plurality of separate laser channels. The multiple separate laser channels are in particular closely adjacent to one another and can each emit light of at least a slightly different wavelength. However, it is also conceivable that the laser channels emit light of essentially the same wavelength.

According to at least one embodiment, the laser package further comprises an optical element which is configured to direct a laser beam emitted by the at least one laser device in the direction of the light exit window. In particular, in the event that the at least one photosensitive area is arranged on the exit window, the laser beam can be deflected onto the at least one photosensitive area by means of an optical element within the laser package. The optical element is part of the laser package and can, for example, comprise a prism and/or a mirror and/or a beam combiner and/or an optical fiber, etc.

The optical element can also be configured to superimpose a light emitted by the first second and third laser device and direct it in the direction of the light exit window.

According to at least one embodiment, the laser package is operated to generate the position marker and the laser beam is redirected to a position on the outside of the package. This area can be photosensitive for permanent marking (e.g. the material of the outside of the package itself or an additional layer). By deflecting the laser beam onto the photosensitive area, it is structured (creation of the position marker). By deflecting the laser beam, the laser profile is marked on the photosensitive area, for example, or a tile of a photosensitive raster pattern is marked. The photosensitive area can also have a reference marker, e.g. as a “reference crosshair” or as a “reference grid”. The reference marker serves in particular as a reference for an analysis (laser light offset) of the laser package. The position of the marking indicates the exact position/direction of the laser beam in relation to the package. If a laser profile is imaged on the photosensitive area, additional information about the laser beam can be made visible on the outside of the package (e.g. fast axis/slow axis ratio).

The advantages of the procedure or laser package mentioned can be as follows:
Generation of at least one position marker by the laser device of the laser package itself
High-precision position marker, independent of the tolerances of the individual components and the build-up process of the laser package.
Generation of the position marker or determination of a laser light offset can be integrated into existing processes (final testing).
Position marker in combination with a reference marker can be used for grouping/binning laser packages
Inexpensive, fast and flexible adjustment of the laser package possible when installing it in an application

### BRIEF DESCRIPTION OF THE DRAWINGS

In the following, embodiments of the invention are explained in more detail with reference to the accompanying drawings. They show, in each case schematically,

FIGS. 1 to 3 Possible types of laser light offset of a laser package;

FIGS. 4 and 5 an isometric view of a method for determining a laser light offset in a laser package and an embodiment of a laser package according to some aspects of the proposed principle, respectively;

FIGS. 6 and 7 an isometric view of a further embodiment of a method for determining a laser light offset in a laser package or a further embodiment of a laser package according to some aspects of the proposed principle; and

FIGS. 8 and 9 a top view of a photosensitive area and a position marker on it.

### DETAILED DESCRIPTION

The following embodiments and examples show various aspects and their combinations according to the proposed principle. The embodiments and examples are not always to scale. Likewise, various elements may be shown enlarged or reduced in size in order to emphasize individual aspects. It is understood that the individual aspects and features of the embodiments and examples shown in the figures can be readily combined with each other without affecting the principle of the invention. Some aspects have a regular structure or shape. It should be noted that slight deviations from the ideal shape may occur in practice without, however, contradicting the inventive concept.

In addition, the individual figures, features and aspects are not necessarily shown in the correct size, and the proportions between the individual elements are not necessarily correct. Some aspects and features are emphasized by enlarging them. However, terms such as “above”, “above”, “below”, “below”, “larger”, “smaller” and the like are shown correctly in relation to the elements in the figures. It is thus possible to deduce such relationships between the elements on the basis of the figures.

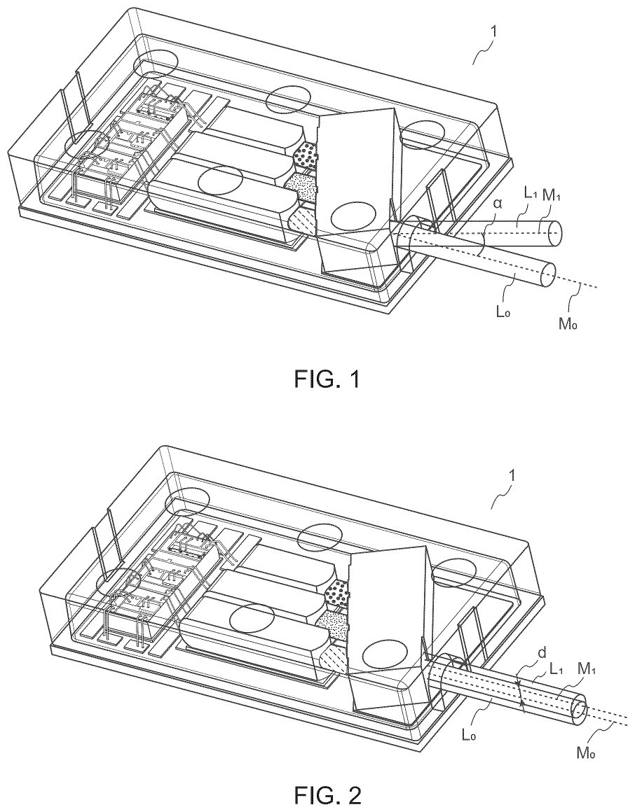

FIGS. 1 to 3 show possible types of laser light offset of a laser package 1, whereby the laser light offset can result, for example, from component tolerances of the individual components of the laser package 1 or tolerances in the manufacturing process of the laser package. The laser light offset can be an offset of the laser beam actually emitted by the laser package with respect to a target position and target direction or with respect to a target exit location and a target axis of a laser beam ideally emitted by the laser package.

As shown in FIG. 1, a laser beam L₁ actually emitted by the laser package 1 or the center axis M₁ of the laser beam L₁ actually emitted by the laser package 1 can, for example, be tilted by an angle α relative to a laser beam L₀ ideally emitted by the laser package or relative to the center axis M₀ of the laser beam L₀ ideally emitted by the laser package 1.

According to FIG. 2, a laser beam L₁ actually emitted by the laser package 1 or the center axis M₁ of the laser beam L₁ actually emitted by the laser package 1 can be shifted parallel by a distance d with respect to the laser beam L₀ ideally emitted by the laser package or with respect to the center axis M₀ of the laser beam L₀ ideally emitted by the laser package 1. Additionally or alternatively, a beam profile S₁ actually emitted by the laser package 1, for example in the form of an ellipse, which has a different beam angle in one direction (fast axis) than in a direction perpendicular to it (slow axis), can be rotated by an angle β around the center axis M₀ of the laser beam L₀ ideally emitted by the laser package 1 compared to a beam profile S₀ ideally emitted by the laser package.

The types of laser light offset of a laser package 1 shown separately in FIGS. 1 to 3 can occur separately for different laser packages depending on the component tolerances of the individual components of the laser package 1, or tolerances in the manufacturing process of the laser package, or can occur in any possible combination of the three types shown.

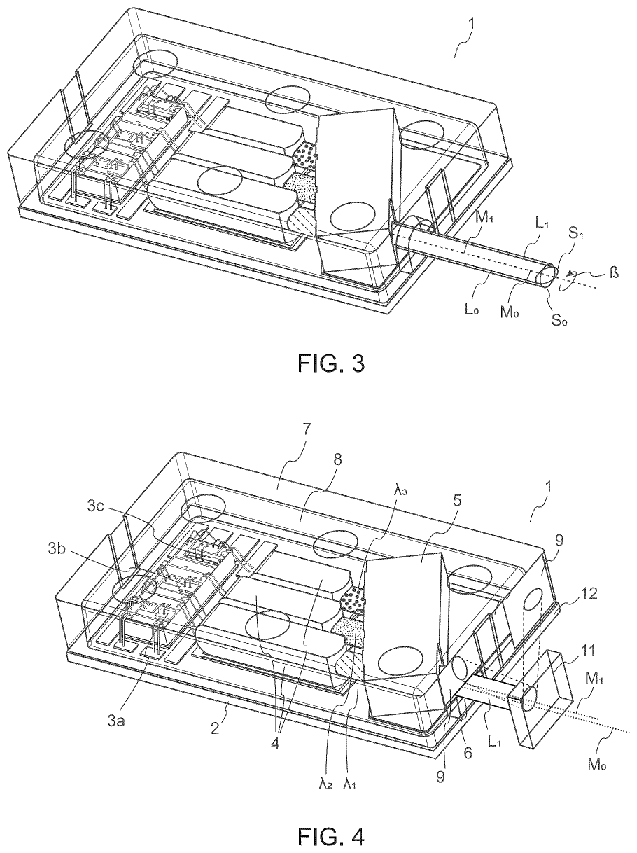

FIG. 4 shows a step of a possible method for determining a laser light offset in a laser package 1 or a method for generating a position marker on the laser package and FIG. 5 shows a corresponding embodiment example of the laser package 1 with the position marker.

The method comprises providing a laser package 1. The laser package 1 comprises a carrier substrate 2 and at least one laser device 3 arranged on the carrier substrate 2 for emitting laser light. The laser package shown in FIG. 4 specifically comprises three laser devices 3a, 3b, 3c, each of which is formed by a laser diode. A first laser diode 3a is configured to emit light of a first wavelength λ₁, a second laser diode 3b to emit light of a second wavelength λ₂ and a third laser diode 3c to emit light of a third wavelength λ₃. The wavelengths λ₁, λ₂, λ₃ can, for example, be laser light of the colors red, green and blue, and the laser package 1 can thus form a so-called RGB laser package.

Downstream of each of the laser devices is a beam shaping or light guide element 4, which directs or guides the laser light emitted by the laser devices 3a, 3b, 3c onto an optical element 5. The optical element 5 is configured to superimpose the laser light emitted by the first second and third laser devices 3a, 3b, 3c within the optical element 5 and to direct the superimposed laser light in the form of a laser beam in the direction of a light exit window 6 of the laser package 1.

The laser package also comprises a housing cover 7, which forms a cavity 8 together with the carrier substrate 2. The laser devices 3a, 3b, 3c, the beam shaping or light guide elements 4 and the optical elements 5 are arranged in the cavity 8. The light exit window 6 is part of the housing cover 7 or arranged inside it and forms a window or opening through which the laser light generated by the laser devices 3a, 3b, 3c is coupled out of the laser package 1 in the form of a laser beam L₁.

The method also comprises providing at least one photosensitive area 9 on a surface of the housing cover 7 located outside the cavity 8. The laser package shown in FIG. 4 specifically comprises two photosensitive areas 9, each of which is arranged on a surface of the housing cover 7 located outside the cavity 8. The photosensitive areas 9 can be provided after the laser package 1 has been assembled, i.e. after the laser package 1 has been provided, or integrated into the manufacturing process of the laser package 1.

To generate a position marker 10 on the photosensitive areas 9, a reflector module 11 is arranged opposite the light exit window and the laser devices 3a, 3b, 3c are energized so that the laser package 1 emits a laser beam L₁ through the light exit window 6. The reflector module 11 is configured and arranged opposite the light exit window 6 in such a way that the laser beam L₁ is deflected in the direction of the two photosensitive areas 9 to generate a position marker 10. The reflector module 11 can, for example, be a prism, a mirror or a comparable element or module, by means of which the laser beam emitted by the laser package is deflected in the direction of the photosensitive areas 9.

The reflector module 11 is arranged at a predefined position in relation to a reference 12 on the housing cover or the carrier substrate, so that the reflector module 11 is always arranged at the same distance and with the same orientation in front of the light exit window 6 of the respective laser package in relation to the reference 12 for different laser packages. As shown in FIG. 4, the reference 12 can be, for example, a lateral outer surface of the carrier substrate or one or more fiducals on the housing cover or the carrier substrate, in relation to which the reflector module 11 is arranged opposite the light exit window 6. Such a mutually referenced arrangement of the reflector module 11 relative to the laser package 1 makes it possible to subsequently make a reproducible statement with regard to a position marker on the photosensitive areas 9 generated by means of the reflector module 11.

The photosensitive areas 9 each have a photosensitive layer or a photosensitive material that discolors or mechanically opens in the areas where the deflected laser beam L₁ strikes the photosensitive material. This discoloration or mechanical opening forms the position marker 10.

By means of the position marker 10, as shown in FIG. 5, a statement can be made about the position and direction of the center axis M₁ of the laser beam L₁ actually emitted from the laser package 1 relative to a nominal position and nominal direction of the center axis M₀ of a laser beam ideally emitted from the laser package. This is due to the fact that the target position and target direction of the center axis M₀ of the laser beam ideally emitted from the laser package is known in relation to the reference 12, and that the position marker 10 is also in relation to the reference 12 due to the reference between the reflector module 11 and the reference 12 and thus also in relation to the target position and target direction of the center axis M₀ of the laser beam ideally emitted from the laser package.

This information can then be used to determine the position and direction of the center axis M₁ of the laser beam L₁ actually emitted from the laser package 1 relative to the target position and target direction of the center axis M₀ of the laser beam ideally emitted from the laser package or an offset between the laser beam actually emitted from the laser package 1 and a laser beam ideally emitted from the laser package.

In the specific embodiment example shown in FIG. 5, the exit position of the center axis M₁ from the laser package of the actually emitted laser beam L₁ is determined by extending the almost axis of the beam profile of the markings generated on the two photosensitive areas 9. The intersection of the two extensions, shown by the two dashed lines, results in the exit position of the center axis M₁ from the laser package 1. The center axis M₀ of the laser beam ideally emitted from the laser package is also shown offset from the center axis M₁ of the laser beam L₁ actually emitted.

Using the position marker 10, the laser package 1 can then be adjusted in an application according to the offset of the actually emitted laser beam L₁ in such a way that the laser beam can be precisely coupled into an element connected to the laser package 1, such as an optical system, without the laser package having to be energized or activated again. The adjustment of the laser package 1, on the other hand, can be carried out passively and, due to the known exit position of the central axis M₁ of the actually emitted laser beam L₁ from the laser package 1, can still be carried out extremely precisely.

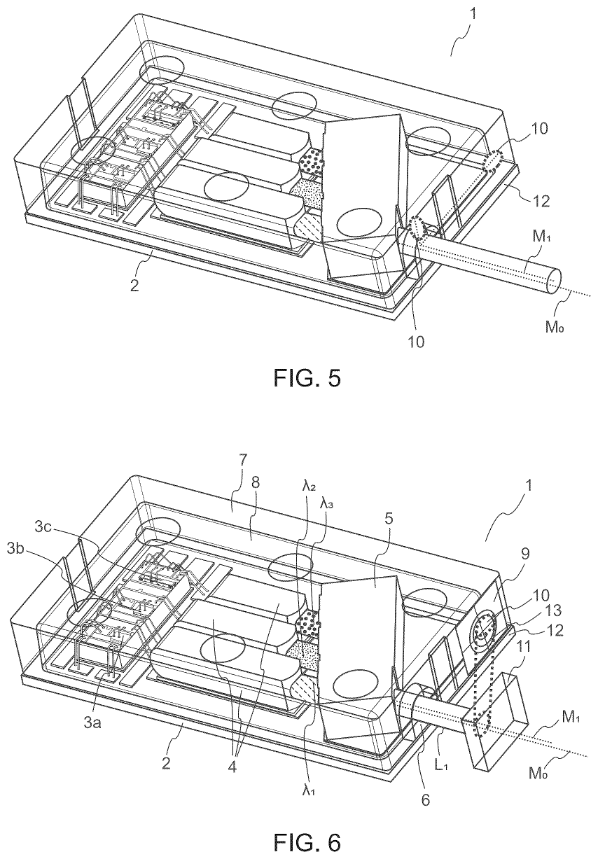

FIG. 6 shows an isometric view of a further embodiment of a method for determining a laser light offset in a laser package and a further embodiment of a method for generating a position marker on the laser package. In contrast to the laser package 1 shown in FIGS. 4 and 5, the laser package shown in FIG. 6 only has a photosensitive area 9 on a surface of the housing cover 7 outside the cavity 8. A reference marker 13 in the form of a crosshair is also printed on the photosensitive area 9.

To generate the position marker 10, a reflector module 11 is also arranged opposite the light exit window 6 of the laser package 1 and the laser devices 3a, 3b, 3c are energized. The laser beam L₁ emitted from the laser package is deflected in the direction of the photosensitive area 9 by the reflector module 11 and the position marker 10 is generated on the photosensitive area 9. The reference marker is in relation to the reference 12 or to the target position of the center axis M₀ of the laser beam ideally emitted from the laser package, so that a position and/or direction offset of the center axis M₁ of the laser beam L₁ with respect to the target position and/or target direction of the center axis M₀ of the laser beam ideally emitted from the laser package can be read off using only the position marker 10 and the reference marker 13. As shown, the reference marker 13 can be, for example, a crosshair painted or printed on the photosensitive area, a coordinate system or another type of target marking.

In the embodiment example of FIG. 7, in contrast to the preceding embodiments, the laser beam L₁ actually emitted to generate the position marker 10 is not deflected by a reflector module 11 in front of the exit window 6 of the laser package 1 in the direction of the photosensitive area 9, but is merely deflected within the laser package 1 by means of the optical element 5 in the direction of the photosensitive area 9. The photosensitive area 9 is located on the exit window 6, and the position marker 10 is created by the laser beam L₁ exposing the rear side of the photosensitive area 9, thereby mechanically opening it in the area of the laser beam L₁. The position marker 10 is generated accordingly by the fact that the photosensitive area 9 is, so to speak, irradiated in the area in which the laser beam L₁ hits the photosensitive area 9. In this case, the position marker 10 can be formed by an opening in the photosensitive layer. In the embodiment shown, a reference marker 13 in the form of a crosshair is also printed on the photosensitive area 9, the center of which corresponds to the central axis M₀ of the laser beam ideally emitted from the laser package. Using only the position marker 10 and the reference marker 13, a position and/or direction offset of the center axis M₁ of the laser beam L₁ with respect to the target position and/or target direction of the center axis M₀ of the laser beam ideally emitted from the laser package can be read.

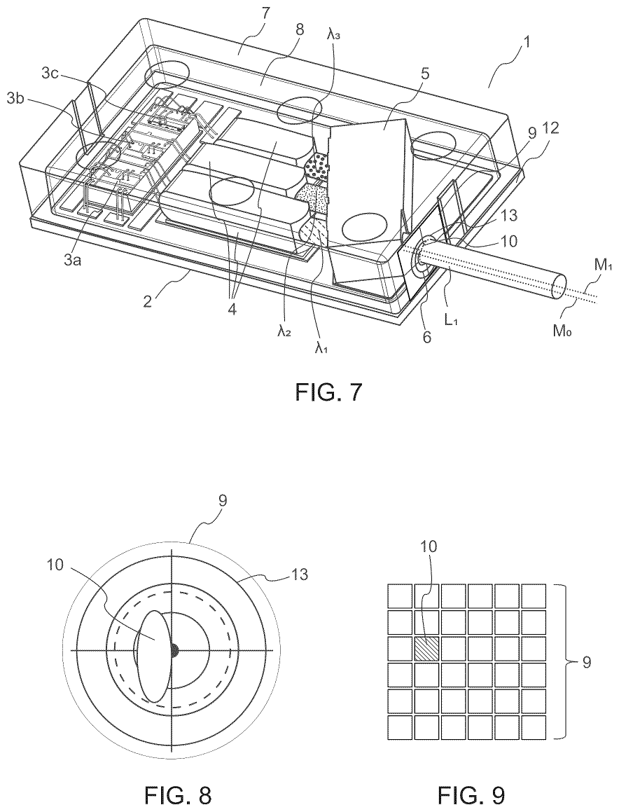

FIGS. 8 and 9 each show a top view of a photosensitive area 9 and a position marker 10 or reference marker 13 located on it. FIG. 8 shows a round photosensitive area 9 on which a reference marker 13 is also printed in the form of a crosshair.

The position marker 10 generated on the photosensitive area 9 is slightly shifted to the left of the center of the crosshairs, from which an offset can be derived between the central axis M₁ of the laser beam L₁ actually emitted by the laser package and the central axis M₀ of the laser beam ideally emitted from the laser package.

The reference marker 13 also has a dotted circle, which can be used to classify the laser package according to its quality (binning). For example, the laser package 1 can be classified as “good” if the position marker 10 lies completely within the dotted circle, or it can be classified as “not good” if the position marker 10 lies at least partially outside the dotted circle.

According to FIG. 9, the photosensitive area 9 can also be formed by an array of several photosensitive sub-areas. The photosensitive sub-areas can each comprise a photosensitive layer or a photosensitive material and be arranged at a distance from one another in a matrix arrangement. There may be areas between the sub-areas that do not comprise photosensitive material. The position marker 10 can, for example, completely color partial areas of the array that have been irradiated with laser light of the highest intensity, but it is also possible that the partial areas that are illuminated by the laser beam L₁ are only partially colored according to the incident laser beam.

It is also possible to sort the laser package into a class according to its quality using the array structure. The classes can be formed by the individual sub-areas or by a subset of the sub-areas. In the present case, for example, the laser package could be sorted into 36 different classes, corresponding to the 36 sub-areas, whereby the laser package falls into the class in relation to which sub-area the photosensitive area 9 has the strongest discoloration. However, it is also possible to combine 4 sub-areas (2×2) into one class, so that the laser package can be sorted into 9 different classes.

What is claimed is:

1. A method for determining a laser light offset in a laser package with a carrier substrate, at least one laser device arranged on the carrier substrate for emitting a laser beam surrounded by a housing cover, wherein the housing cover comprises a light exit window through which a laser beam) is emitted from the laser package during the intended use of the laser package; comprising:
providing the laser package with at least one photosensitive area on a surface of the housing cover and/or carrier substrate;
energizing the at least one laser device so that it emits a laser beam; and
deflecting the emitted laser beam in the direction of the at least one photosensitive area to generate a position marker on the at least one photosensitive area;
wherein the position marker indicates the position and/or direction of the center axis of the laser beam relative to a target position and/or target direction, and
wherein the position marker and/or target position and/or target direction is in relation to at least one reference on the housing cover and/or the carrier substrate.

2. The method according to claim 1, wherein deflecting the laser beam comprises arranging a reflector module opposite the light exit window.

3. The method according to claim 2, wherein the reflector module is arranged in relation to the at least one reference opposite the light exit window.

4. The method according to claim 1, wherein the position marker is generated by exposing the at least one photosensitive region to the laser beam.

5. The method according to claim 1, wherein the at least one photosensitive region is formed by an array of a plurality of photosensitive subregions.

6. The method according to claim 1, further comprising providing a reference marker, in particular a crosshair, in the region of the at least one photosensitive region, wherein an offset between the reference marker and the position marker indicates a position and/or direction offset of the center axis of the laser beam with respect to the target position and/or target direction.

7. The method according to claim 6, wherein the reference marker is in relation to the at least one reference on the housing cover and/or the carrier substrate.

8. The method according to claim 6, further comprising sorting the laser package into a class, wherein the laser package is sorted into a class according to the position of the position marker relative to the reference marker.

9. The method according to claim 1, wherein the at least one photosensitive region is arranged on the light exit window, and the position marker is generated by radiating through the at least one photosensitive region.

10. A laser package comprising:
a carrier substrate;
at least one laser device arranged on the carrier substrate, which is configured to emit a laser beam;
a housing cover which is arranged on the carrier substrate and forms a cavity with the carrier substrate, wherein the at least one laser device is arranged in the cavity, and wherein the housing cover comprises a light exit window through which a laser beam is emitted from the laser package during intended use of the laser package;
at least one photosensitive area on a surface of the housing cover and/or carrier substrate lying outside the cavity; and
a position marker on the at least one photosensitive region, wherein the position marker indicates the position and/or direction of the center axis of the laser beam emitted during the intended use of the laser package relative to a target position and/or target direction,
wherein the position marker and/or target position and/or target direction is in relation to at least one reference on the housing cover and/or the carrier substrate.

11. The laser package according to claim 10, wherein the at least one photosensitive region is formed by an array of a plurality of photosensitive subregions.

12. The laser package according to claim 10, further comprising a reference marker, in particular a crosshair, in the region of the at least one photosensitive region, wherein an offset between the reference marker and the position marker indicates a position and/or direction offset of the center axis of the laser beam emitted during the intended use of the laser package with respect to the target position and/or target direction.

13. The laser package according to claim 12, wherein the reference marker is in relation to the at least one reference on the housing cover and/or the carrier substrate.

14. The laser package according to claim 10, wherein the at least one photosensitive region is arranged on the light exit window.

15. The laser package according to claim 10, further comprising an optical element configured to direct a laser beam emitted by the at least one laser device in the direction of the light exit window.

16. The laser package according to claim 10, wherein the laser package comprises a first, a second and a third laser device, and wherein the first laser device is configured to emit red laser light, the second laser device is configured to emit green laser light and the third laser device is configured to emit blue laser light.

17. The laser package according to claim 16, further comprising an optical element configured to superimpose a laser light emitted by the first second and third laser devices and to direct it in the direction of the light exit window.
